(19) United States
(12) Patent Application Publication
(10) Pub. No.: US 2026/0354032 A1
(43) Pub. Date: Nov. 5, 2026

(54) MAGNETIC MEMORY ELEMENT AND MAGNETIC MEMORY DEVICE

(71) Applicant: The University of Tokyo, Tokyo (JP)

(72) Inventors: Satoru Nakatsuji, Tokyo (JP); Akito Sakai, Tokyo (JP)

(73) Assignee: The University of Tokyo, Tokyo (JP)

(21) Appl. No.: 19/125,377

(22) PCT Filed: Oct. 30, 2023
(86) PCT No.: PCT/JP2023/039096

§ 371 Date: Apr. 29, 2025

(30) Foreign Application Priority Data
Oct. 31, 2022 (JP) 2022-175132

(51) Int. Cl. H10N 50/10; G11C 11/16; H10N 50/85; H10N 52/85

(52) U.S. Cl. CPC H10N 50/10; G11C 11/161; G11C 11/1673; G11C 11/1675; H10N 50/85; H10N 52/85

(57) ABSTRACT

A magnetic memory element includes a magnetoresistance element including a free layer having a reversible magnetic order, a fixed layer having a fixed magnetic order, and a non-magnetic layer disposed between the free layer and the fixed layer. At least one of the free layer and the fixed layer is made of a topological ferrimagnet that exhibits an anomalous Hall effect and an anomalous Nernst effect.

### TECHNICAL FIELD

The present invention relates to a magnetic memory element and a magnetic memory device.

### BACKGROUND ART

In recent years, ferromagnet-based magnetic random-access memories (MRAMs) have attracted attention as low-power non-volatile magnetic memory devices for information processing. In fact, various semiconductor manufacturers employ MRAMs as alternatives to volatile memories such as static random-access memories (SRAMs). Examples of such MRAMs include an STT-MRAM that allows reversal of magnetization of a ferromagnet by a spin transfer torque (STT) and an SOT-MRAM that allows reversal of magnetization of a ferromagnet by a spin-orbit torque (SOT) (e.g., See Patent Literature 1).

### CITATION LIST

### Patent Literature

Patent Literature 1: U.S. Pat. No. 9,837,602

### SUMMARY OF INVENTION

### Technical Problem

Unfortunately, since the current MRAMs use ferromagnets, the magnetization reversal speed is limited to about one nanosecond, making them unsuitable as alternatives to SRAMs. Additionally, ferromagnets are generally sensitive to disturbances from external magnetic fields.

The invention has been made in view of the foregoing, and an object of the invention is to provide a magnetic memory element and a magnetic memory device that use a ferrimagnet to enhance resistance to disturbances from external magnetic fields and achieve high-speed processing.

### Solution to Problem

A magnetic memory element according to one aspect of the invention includes a magnetoresistance element including a free layer having a reversible magnetic order, a fixed layer having a fixed magnetic order, and a non-magnetic layer disposed between the free layer and the fixed layer. At least one of the free layer and the fixed layer is made of a topological ferrimagnet that exhibits an anomalous Hall effect and an anomalous Nernst effect.

A magnetic memory device according to one aspect of the invention includes a plurality of magnetic memory elements. Each of the plurality of magnetic memory elements is defined as the magnetic memory element described above.

A magnetic memory element according to another aspect of the invention includes: a ferrimagnetic layer made of a topological ferrimagnet that exhibits an anomalous Hall effect and an anomalous Nernst effect; and a spin Hall layer in contact with the ferrimagnetic layer and made of a material that exhibits a spin Hall effect, a write current flowing through the spin Hall layer in an in-plane direction being configured to generate a spin current in an out-of-plane direction. The spin current is configured to induce a spin-orbit torque that allows reversal of a magnetic order of the topological ferrimagnet in the ferrimagnetic layer. A read current flowing through the ferrimagnetic layer in the in-plane direction is configured to generate an in-plane Hall voltage by the anomalous Hall effect in a direction perpendicular to the read current.

A magnetic memory device according to another aspect of the invention includes a plurality of magnetic memory elements. Each of the plurality of magnetic memory elements is defined as the magnetic memory element described above.

### Advantageous Effects of Invention

According to the invention, because the magnetic memory element uses a topological ferrimagnet that exhibits the anomalous Hall effect and the anomalous Nernst effect, it is possible to enhance resistance to disturbances from external magnetic fields and achieve high-speed processing.

### BRIEF DESCRIPTION OF DRAWINGS

FIG. 1 is a graph of a relationship between the magnetization and a transverse thermoelectric coefficient for various magnetic materials.

FIG. 2A is a graph of magnetic field dependence of Hall resistivity for Gd₂Co₇ and HO_{1.2}Gd_{0.8}Co₇.

FIG. 2B is a graph of temperature dependence of Hall resistivity for Gd₂Co₇ and HO_{1.2}Gd_{0.8}CO₇.

FIG. 2C is a graph of magnetic field dependence of Hall resistivity for GdCo₅.

FIG. 2D is a graph of temperature dependence of Hall resistivity for GdCo₅.

FIG. 3A is a cross-sectional view of a magnetoresistance element having a first memory structure according to a first embodiment.

FIG. 3B is a cross-sectional view of a magnetoresistance element having a second memory structure according to the first embodiment.

FIG. 3C is a cross-sectional view of a magnetoresistance element having a third memory structure according to the first embodiment.

FIG. 4 is a graph of a relationship between saturation magnetization and uniaxial magnetic anisotropy energy for various magnetic materials.

FIG. 5 is a schematic view of a configuration of a magnetic memory element for an SOT-MRAM.

FIG. 6 is a schematic view of a configuration of a magnetic memory element for an STT-MRAM.

FIG. 7 is a schematic view of a configuration of a magnetic memory element using all-optical toggle switching.

FIG. 8 is a schematic view of a configuration of a magnetic memory element according to a second embodiment.

### DESCRIPTION OF EMBODIMENTS

Exemplary embodiments of the invention will be described below with reference to the accompanying drawings. The same reference signs are used to designate the same or similar elements throughout the drawings. The drawings are schematic, and a relationship between a planar dimension and a thickness and a thickness ratio between members are different from reality. Needless to say, there are portions having different dimensional relationships or ratios between the drawings.

To realize a non-volatile magnetic memory device that is resistant to disturbances from external magnetic fields and can operate at high speed, the embodiments focus on ferrimagnets, which have a smaller magnetization than ferromagnets.

A ferrimagnet has two different magnetic ions that are antiferromagnetically coupled, causing their sublattice magnetizations to cancel each other out and resulting in a small net magnetization. In certain ferrimagnets, the sum of the two sublattice magnetizations can vanish by adjusting the temperature or the concentration of the two magnetic ions. This temperature or concentration is called a magnetization compensation point. By tuning the temperature or composition, the net magnetization of the ferrimagnet can be reduced to nearly zero, thereby enhancing its resistance to disturbances from external magnetic fields.

If the two magnetic ions have different g-factors (which describe the relationship between a magnetic moment and its angular momentum), an angular momentum compensation point exists, where the angular momenta of the two sublattices cancel each other out, resulting in a net angular momentum of zero. In a ferrimagnet where the magnetization compensation point and the angular momentum compensation point are different, a finite magnetization remains at the angular momentum compensation point, where the speed of magnetic dynamics-such as the precession of the magnetic moment and the velocity of domain walls-reaches its maximum, enabling rapid magnetization reversal. By adjusting the concentration of the magnetic ions in the ferrimagnet, it is possible to pre-adjust the angular momentum compensation point to match the operating temperature of a magnetic memory element (e.g., around room temperature).

To employ a ferrimagnet in a magnetic memory element, a magnetic response is required that allows the magnitude of the magnetization to be clearly detectable, despite its small value. The embodiments are directed to topological ferrimagnets, which can exhibit a response much larger than expected from the magnitude of the magnetization due to the topology of the electronic states.

Examples of such a topological ferrimagnet include an alloy (R-TM) of a rare-earth element (R) and a 3 d transition metal (TM), Mn₅Ge₂, Mn₃Ga, Mn₃SnN, and Mn₄N. Examples of TM of R-TM include cobalt (Co) or iron (Fe). Let the composition of R-TM be denoted by RₓTM_{y}. The ratio of R to TM (x/y) is preferably in a range of 0.2 to 0.5. The R of R-TM may be a combination of two different rare-earth elements.

The topological ferrimagnets of the embodiments exhibit both the anomalous Hall effect and the anomalous Nernst effect despite their tiny magnetization.

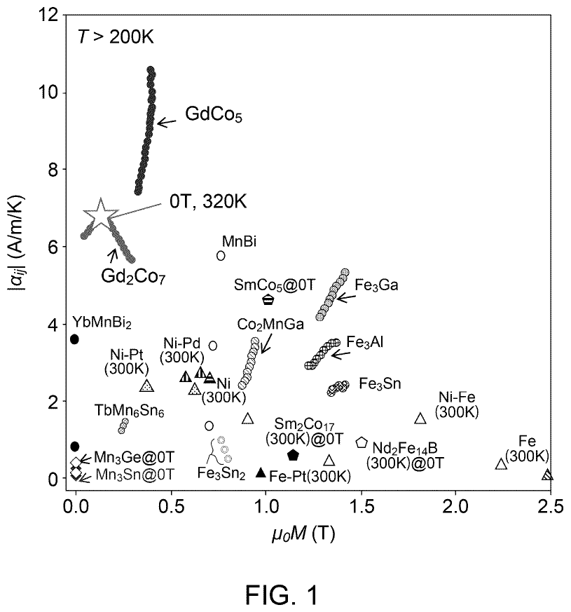

FIG. 1 shows a relationship between μ₀M (where μ₀ is vacuum permeability and M is the magnetization) and an absolute value of the transverse thermoelectric coefficient αᵢⱼ at a temperature T>200K for various magnetic materials. FIG. 1 indicates that |αᵢⱼ| of Gd₂Co₇ and GdCo₅ is particularly large. |αᵢⱼ| of GdCo₅ at 350K well exceeds 10 A/m/K, and |αᵢⱼ| of Gd₂Co₇ at 320K is approaching a value close to 7 A/m/K at zero magnetic field (OT), indicating that GdCo₅ and Gd₂Co₇ exhibit the large anomalous Nernst effect.

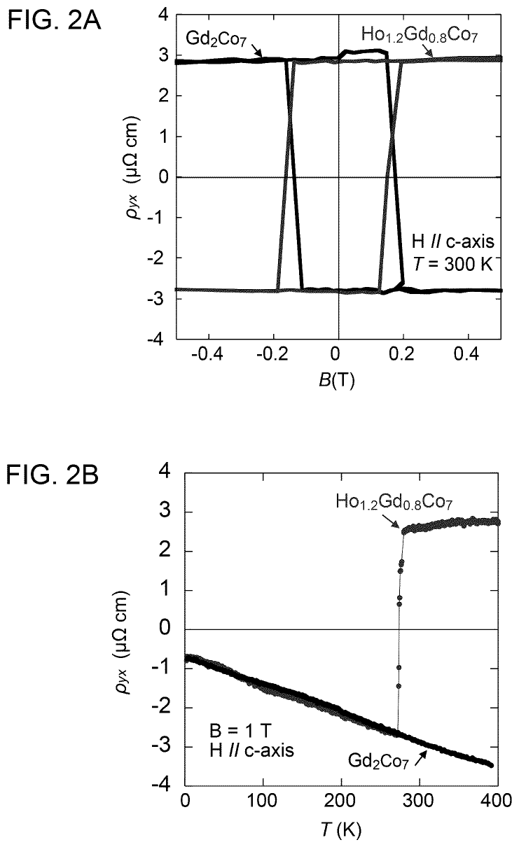

FIG. 2A shows the magnetic field dependence of Hall resistivity ρ_{yx} for Gd₂Co₇ and HO_{1.2}Gd_{0.8}Co₇ at 300K (room temperature) under the magnetic field B parallel to c-axis. FIG. 2B shows the temperature dependence of Hall resistivity ρ_{yx} for Gd₂Co₇ and Ho_{1.2}Gd_{0.8}Co₇ under the magnetic field B of 1 T parallel to c-axis. FIGS. 2A and 2B indicate that Gd₂Co₇ and Ho_{1.2}Gd_{0.8}Co₇ exhibit the large anomalous Hall effect. FIG. 2A reveals that a magnetic order (magnetization) of Gd₂Co₇ and Ho_{1.2}Gd_{0.8}Co₇ is reversed at around ±0.2 T at room temperature. FIG. 2B reveals that the magnetic order of Ho_{1.2}Gd_{0.8}Co₇ is reversed at around 270K.

FIG. 2C shows the magnetic field dependence of Hall resistivity ρ_{yx} for GdCo₅ at 100K, 200K, and 300K when an electric current I flows parallel to [2-1-10] under the magnetic field B parallel to [0001]. FIG. 2D shows the temperature dependence of Hall resistivity ρ_{yx} for GdCo₅ when the electric current I flows parallel to [2-1-10] under the magnetic field B of 2 T parallel to [0001]. FIGS. 2C and 2D indicate that GdCo₅ also exhibits the anomalous Hall effect. FIG. 2C reveals that coercivity is observed at 200K or below and the coercivity increases as the temperature decreases. FIG. 2D reveals that the magnitude of the Hall resistivity ρ_{yx} monotonically increases as the temperature increases.

The properties of topological ferrimagnets, which exhibit the large anomalous Hall effect and the large anomalous Nernst effect despite their tiny magnetization, arise from their crystal and band structures. Among the topological ferrimagnets, R₂Co₇ and RCo₅ have a rhombohedral or a hexagonal crystal structure. The topological ferrimagnets have a topological band structure near the Fermi surface. For example, R₂Co₇ and RCo₅ have a flat band near the Fermi surface, indicating that energy does not change even when momentum changes. This suggests that 4f electrons in R or 3 d electrons in Co are localized in real space.

Next, the magnetic memory elements using the topological ferrimagnets will be described. In the following description, the first embodiment is directed to the magnetic memory elements that use a magnetoresistance effect to read data, and the second embodiment is directed to the magnetic memory elements that use the anomalous Hall effect to read data.

### First Embodiment

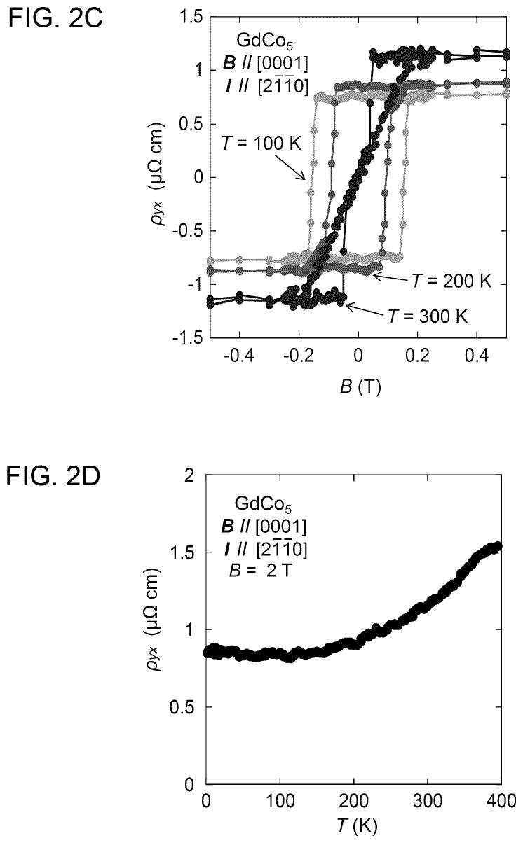

The first embodiment of the invention will be described with reference to FIGS. 3A to 7. The first embodiment is directed to three types of structures for the magnetic memory elements (first to third memory structures).

FIG. 3A shows a cross-sectional view of a magnetoresistance element 100 having the first memory structure. The magnetoresistance element 100 includes a free layer 112 having a reversible magnetic order, a non-magnetic layer 114, and a fixed layer 116 having a fixed magnetic order. The non-magnetic layer 114 is disposed between the free layer 112 and the fixed layer 116.

The non-magnetic layer 114 is made of an insulator such as MgO, Al₂O₃, and HfO. The free layer 112 includes a ferrimagnetic layer 1121 made of a topological ferrimagnet and a first ferromagnetic layer 1123 that is made of a ferromagnet, sandwiched between the non-magnetic layer 114 and the ferrimagnetic layer 1121, and has a thickness of 1 nm or less (several atomic layers).

Preferably, the topological ferrimagnet of the ferrimagnetic layer 1121 is an alloy of a rare-earth element and a 3 d transition metal, and is a ferrimagnet at the angular momentum compensation point. Examples of the ferromagnet of the first ferromagnetic layer 1123 include CoFeB or CoFe. Stacking the ferrimagnetic layer 1121 on the ultra-thin first ferromagnetic layer 1123 causes a magnetic coupling (i.e., exchange coupling) between the topological ferrimagnet and the ferromagnet, allowing a high-speed reversal of the magnetic order in the free layer 112.

The fixed layer 116 includes a synthetic antiferromagnetic layer 118, a bridge layer 1163 stacked on the synthetic antiferromagnetic layer 118 and made of metal such as tantalum (Ta), and a second ferromagnetic layer 1161 stacked on the bridge layer 1163 and in contact with the non-magnetic layer 114.

The second ferromagnetic layer 1161 is made of the same ferromagnet as the first ferromagnetic layer 1123. Here, the stacking structure of the second ferromagnetic layer 1161/non-magnetic layer 114/first ferromagnetic layer 1123 is preferably CoFe/Mg/CoFe or CoFeB/MgO/CoFeB. This is because a magnetic tunnel junction (MTJ) element with such a stacking structure has a large tunneling magnetoresistance (TMR) ratio. In particular, the MTJ element with CoFeB/MgO/CoFeB structure is known to have TMR ratio of 200% or more at room temperature.

The synthetic antiferromagnetic layer 118 includes a first multi-layer film 1165, a spacer layer 1167 made of metal such as ruthenium (Ru), and a second multi-layer film 1169. The spacer layer 1167 is sandwiched between the first multi-layer film 1165 and the second multi-layer film 1169. For example, the first multi-layer film 1165 is a multi-layer film (Co/Pt)ₙ with multiple (n) Co/Pt bilayers made by alternating layers of Co and Pt, and the second multi-layer film 1169 is a multi-layer film (Co/Pt) m with multiple (m) Co/Pt bilayers made by alternating layers of Co and Pt. These Co/Pt multi-layer films exhibit magnetic anisotropy in an out-of-plane direction at an interface of Co/Pt, thereby exhibiting perpendicular magnetization.

The second ferromagnetic layer 1161 is ferromagnetically coupled to the perpendicularly magnetized first multi-layer film 1165 via the bridge layer 1163 to enhance the coercivity of the second ferromagnetic layer 1161. The first multi-layer film 1165 is coupled to the second multi-layer film 1169 in an anti-parallel fashion via the spacer layer 1167 to prevent leakage of the magnetic field from the fixed layer 116 to the free layer 112.

As described above, since the topological ferrimagnet is used in the free layer 112, it is possible to enhance resistance to disturbances from external magnetic fields and achieve high-speed processing.

Next, a magnetoresistance element having the second memory structure will be described. FIG. 3B shows a cross-sectional view of the magnetoresistance element 102 having the second memory structure. The magnetoresistance element 102 includes a free layer 122 having a reversible magnetic order, a non-magnetic layer 124, and a fixed layer 126 having a fixed magnetic order. The non-magnetic layer 124 is disposed between the free layer 122 and the fixed layer 126.

The free layer 122 includes a first ferromagnetic layer 1223 stacked on the non-magnetic layer 124, and a first ferrimagnetic layer 1221 stacked on the first ferromagnetic layer 1223. The fixed layer 126 includes a second ferrimagnetic layer 1263 made of the topological ferrimagnet, and a second ferromagnetic layer 1261 stacked on the second ferrimagnetic layer 1263 and in contact with the non-magnetic layer 124. The fixed layer 126 of the magnetoresistance element 102 has a less complex stacking structure than the fixed layer 116 including the synthetic antiferromagnetic layer 118 shown in FIG. 3A.

The first ferrimagnetic layer 1221, the first ferromagnetic layer 1223, the non-magnetic layer 124, and the second ferromagnetic layer 1261 of the magnetoresistance element 102 shown in FIG. 3B have the same structures as those of the ferrimagnetic layer 1121, the first ferromagnetic layer 1123, the non-magnetic layer 114, and the second ferromagnetic layer 1161 of the magnetoresistance element 100 shown in FIG. 3A, respectively, so the explanation will be omitted.

The topological ferrimagnet constituting the second ferrimagnetic layer 1263 is preferably a ferrimagnet near the magnetization compensation point. Here, a magnetic hardness parameter k is introduced, which is defined by formula (1).

$$κ = \sqrt{{K}_{u} / {μ}_{0} {M}_{s}^{2}} \qquad ( 1 )$$

In formula (1), Kᵤ, μ₀, and Mₛ denote the uniaxial magnetic anisotropy energy, the vacuum permeability, and the saturation magnetization, respectively.

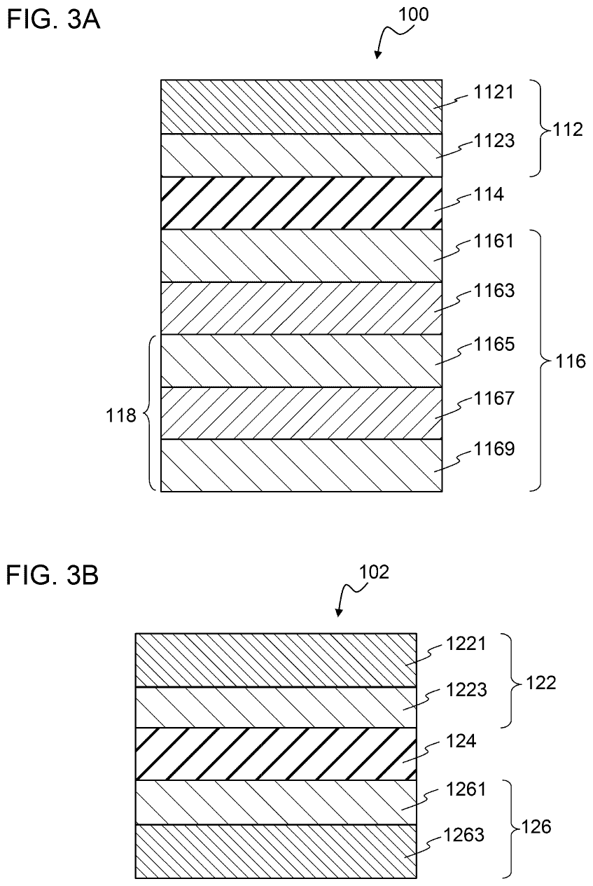

FIG. 4 shows a relationship between μ₀Mₛ and Kᵤ for various magnetic materials. In FIG. 4, κ=0.1, κ=1, and κ=10 are represented by dash-dotted line, dotted line, and solid line, respectively. κ<0.1 indicates soft magnetic materials, 0.1≤κ<1 indicates semi-hard magnetic materials, 1≤κ<10 indicates hard magnetic materials, and κ≥10 indicates ultra-hard magnetic materials. FIG. 4 suggests that the topological ferrimagnets including YCo₅, GdCo₅, Y₂Co₇, Gd₂Co₇, and HO_{1.2}Gd_{0.8}Co₇ are magnetically very hard magnetic materials with κ of 1 or higher. In particular, GdCo₅, Gd₂Co₇, and Ho_{1.2}Gd_{0.8}Co₇ are found to be magnetically harder than Sm—Co based and Nd—Fe—B based permanent magnets.

If the topological ferrimagnet with κ≥1 is employed in the second ferrimagnetic layer 1263, a sufficiently large thermal stability can be secured even if it is small in volume. Since Mₛ of the topological ferrimagnet near the magnetization compensation point is almost zero, the value of κ becomes large even if Kᵤ is small as is clear from formula (1). This makes it possible to obtain a large coercivity. A thin film of the topological ferrimagnet made of the rare-earth element and the 3 d transition metal exhibits bulk perpendicular magnetic anisotropy, making it possible to achieve the fixed layer 126 with perpendicular magnetization.

As described above, in the magnetoresistance element 102, the topological ferrimagnet at the angular momentum compensation point is employed in the first ferrimagnetic layer 1221 of the free layer 122, and the topological ferrimagnet with κ≥1 around the magnetization compensation point is employed in the second ferrimagnetic layer 1263 of the fixed layer 126. In the topological ferrimagnet made of the rare-earth element and the 3 d transition metal, the magnetization compensation point and the angular momentum compensation point are different, and the angular momentum compensation point exists near the magnetization compensation point. Therefore, the compositions (which refer to the ratio of the rare-earth element to the 3 d transition metal) of the topological ferrimagnet of the first ferrimagnetic layer 1221 and the topological ferrimagnet of the second ferrimagnetic layer 1263 are slightly different. The compositions can be tuned by adjusting the concentration of the magnetic ions constituting the topological ferrimagnets.

In an alternative configuration, the free layer 122 of the magnetoresistance element 102 of FIG. 3B may include only the first ferromagnetic layer 1223 with an appropriate thickness without disposing the first ferrimagnetic layer 1221.

Next, a magnetoresistance element having the third memory structure will be described. FIG. 3C shows a cross-sectional view of the magnetoresistance element 104 having the third memory structure. The magnetoresistance element 104 includes a free layer 132 having a reversible magnetic order, a non-magnetic layer 134, and a fixed layer 136 having a fixed magnetic order. The non-magnetic layer 134 is disposed between the free layer 132 and the fixed layer 136.

The non-magnetic layer 134 is made of the same material (such as MgO) as that of the non-magnetic layer 114 of FIG. 3A and the non-magnetic layer 124 of FIG. 3B.

The free layer 132 is made of the topological ferrimagnet at the angular momentum compensation point, and the fixed layer 136 is made of the topological ferrimagnet with κ≥1 around the magnetization compensation point. Each of the topological ferrimagnets is an alloy of the rare-earth element and the 3 d transition metal. In the free layer 132 and the fixed layer 136, the concentration of the rare-earth element increases with increasing distance from the non-magnetic layer 134 in an out-of-plane direction, and the concentration of the 3 d transition metal increases with decreasing distance from the non-magnetic layer 134 in the out-of-plane direction. For example, when the free layer 132 and the fixed layer 136 are formed by sputtering, the amount of the rare-earth element may be adjusted using a shutter.

This concentration gradient in the free layer 132 and the fixed layer 136 results in a structure where the insulator (MgO) is sandwiched between the 3 d transition metals (Co or Fe), thereby enhancing the TMR ratio.

The free layer 132 of the magnetoresistance element 104 of FIG. 3C does not necessarily need to contain the topological ferrimagnet and may be made solely of a ferromagnet such as CoFe or CoFeB.

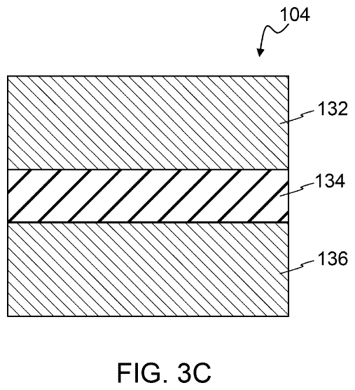

The magnetoresistance elements 100, 102, and 104 shown in FIGS. 3A to 3C, respectively, can be applied to various magnetic memory elements and magnetic memory devices which are different in data writing method. The magnetic memory elements and the magnetic memory devices using the data writing methods of the spin-orbit torque (SOT), the spin transfer torque (STT), and all-optical toggle switching will be explained below with reference to FIGS. 5 to 7, respectively.

FIG. 5 shows a configuration of a magnetic memory element 200 for an SOT-MRAM that allows reversal of a magnetic order (magnetization) by SOT. The magnetic memory element 200 includes a magnetoresistance element 210, a spin Hall layer 220, a first terminal 231, a second terminal 232, a third terminal 233, and transistors Tr1 and Tr2.

The spin Hall layer 220 is made of a material that exhibits a spin Hall effect (hereinafter referred to as a spin Hall material). Examples of the spin Hall material include a non-magnetic heavy metal, such as tantalum (Ta), tungsten (W) and platinum (Pt), or a chalcogenide material such as a topological insulator. The magnetoresistance element 210 includes a free layer 212 which is stacked on the spin Hall layer 220 and whose magnetic order in an out-of-plane direction is reversible, a non-magnetic layer 214 stacked on the free layer 212, and a fixed layer 216 which is stacked on the non-magnetic layer 214 and whose magnetic order is fixed in the out-of-plane direction. Any one of the magnetoresistance elements 100, 102, and 104 shown in FIGS. 3A to 3C may be employed as the magnetoresistance element 210.

The first terminal 231, the second terminal 232, and the third terminal 233 are made of a metal. The first terminal 231 is connected to the fixed layer 216, the second terminal 232 is connected to one end portion of the spin Hall layer 220, and the third terminal 233 is connected to the other end portion of the spin Hall layer 220. The first terminal 231 is connected to a ground line 240. The ground line 240 is set to a ground voltage. The ground line 240 may be set to a reference voltage other than the ground voltage.

Each of the transistors Tr1 and Tr2 is, for example, an N-channel metal oxide semiconductor (NMOS) transistor. The second terminal 232 is connected to a drain of the transistor Tr1, and the third terminal 233 is connected to a drain of the transistor Tr2. Gates of the transistors Tr1 and Tr2 are connected to a word line WL. Sources of the transistors Tr1 and Tr2 are connected to a first bit line BL1 and a second bit line BL2, respectively.

To write data into the magnetoresistance element 210, a weak bias field is applied in a direction of a write current I_{write}. The bias field affects the magnetic order in the out-of-plane direction of the free layer 212, and determines a rotational direction of the magnetic order. The word line WL is set to high level to turn on the transistors Tr1 and Tr2, one of the first bit line BL1 and the second bit line BL2 is set to high level, and the other bit line is set to low level. With these settings, the write current I_{write} (pulsed current) flows through the spin Hall layer 220 in an in-plane direction between the first bit line BL1 and the second bit line BL2 to generate a spin current in the out-of-plane direction, which induces an SOT to allow reversal of the magnetic order of the free layer 212 and thereby write the data. Data to be written can be changed depending on the direction of the write current I_{write}. Here, the pulse width of the write current I_{write} is 20 ps to 50 ps.

To read out the data stored in the magnetoresistance element 210, the word line WL is set to high level to turn on the transistors Tr1 and Tr2, one of the bit lines (second bit line BL2) is set to high level, and the other of the bit lines (first bit line BL1) is set to an open state. With these settings, a read current I_{read} flows from the second bit line BL2 in high level into the ground line 240 through the third terminal 233, the spin Hall layer 220, the free layer 212, the non-magnetic layer 214, the fixed layer 216, and the first terminal 231. By measuring the magnitude of the read current I_{read} by the magnetoresistance effect, it is possible to determine the resistance state of the magnetoresistance element 210, i.e., the stored data.

A plurality of magnetic memory elements 200 may be arranged in a matrix to constitute a magnetic memory device.

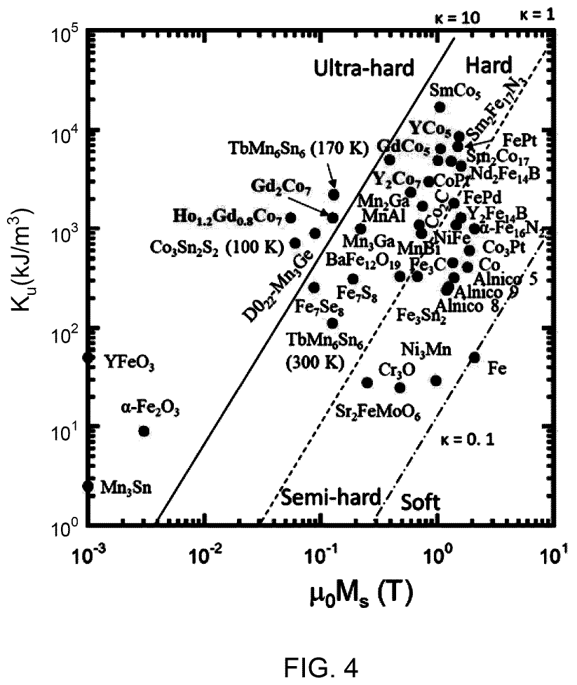

FIG. 6 shows a configuration of a magnetic memory element 300 for an STT-MRAM whose magnetic order (magnetization) is reversed by STT. The magnetic memory element 300 includes a magnetoresistance element 310, a first terminal 321, a second terminal 322, and a transistor Tr.

The magnetoresistance element 310 includes a fixed layer 316 whose magnetic order is fixed in an out-of-plane direction, a non-magnetic layer 314 stacked on the fixed layer 316, and a free layer 312 which is stacked on the non-magnetic layer 314 and whose magnetic order in the out-of-plane direction is reversible. Any one of the magnetoresistance elements 100, 102, and 104 shown in FIGS. 3A to 3C may be employed as the magnetoresistance element 310.

The first terminal 321 and the second terminal 322 are made of a metal. The free layer 312 is connected to the first terminal 321, and the fixed layer 316 is connected to the second terminal 322. The first terminal 321 is connected to a bit line BL, and the second terminal 322 is connected to the transistor Tr.

The transistor Tr is, for example, an NMOS transistor. The transistor Tr has a drain connected to the second terminal 322, a source connected to a source line SL, and a gate connected to a word line WL.

To write data into the magnetoresistance element 310, the word line WL is set to high level to turn on the transistor Tr, and a write current I_{write} flows in the out-of-plane direction between the bit line BL and the source line SL. This induces an STT to allow reversal of the magnetic order of the free layer 312 and thereby write the data. Data to be written can be changed depending on the direction of the write current I_{write}.

To read out the data stored in the magnetoresistance element 310, the word line WL is set to high level to turn on the transistor Tr, and a read current I_{read} flows between the bit line BL and the source line SL. By measuring the magnitude of the read current I_{read} by the magnetoresistance effect, it is possible to determine the resistance state of the magnetoresistance element 310, i.e., the stored data.

A plurality of magnetic memory elements 300 may be arranged in a matrix to constitute a magnetic memory device.

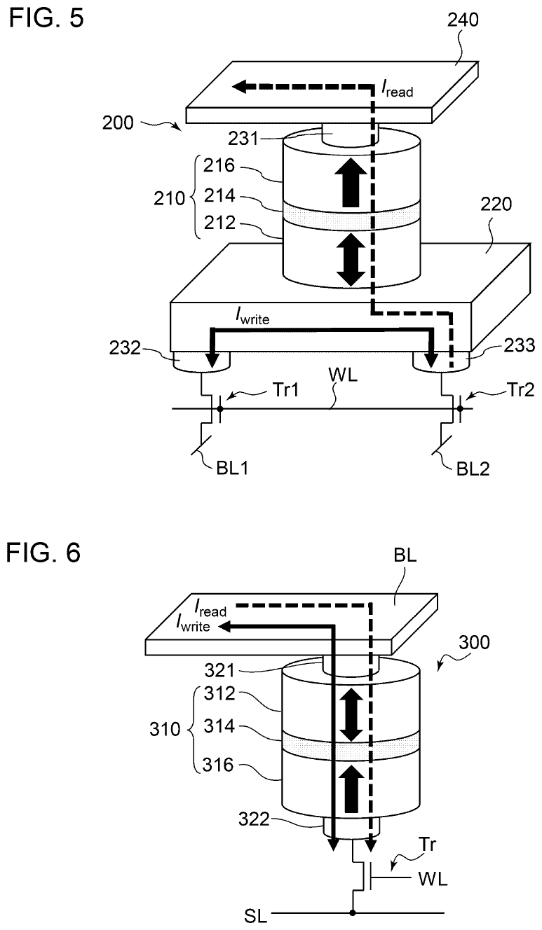

Next, a magnetic memory element using all-optical toggle switching will be explained with reference to FIG. 7.

The magnetic memory element 400 shown in FIG. 7 includes a magnetoresistance element 410 and a capping layer 420 stacked on the magnetoresistance element 410. The magnetoresistance element 410 includes a free layer 412 having a reversible magnetic order (magnetization), a fixed layer 416 having a magnetic order fixed in an out-of-plane direction, and a non-magnetic layer 414 disposed between the free layer 412 and the fixed layer 416. The capping layer 420 is stacked on the free layer 412.

The capping layer 420 is made of an insulator such as Al₂O₃ and MgO. Any one of the magnetoresistance elements 100, 102, and 104 shown in FIGS. 3A to 3C may be employed as the magnetoresistance element 410.

The free layer 412 including the ferrimagnetic layer is irradiated with pulse amplitude modulated femtosecond laser by a light irradiation unit 430. The light irradiation unit 430 includes a light emission unit 432 and a lens 434. The light emission unit 432 emits ultrashort pulsed laser PL with a pulse width of about 100 fs. The pulsed laser PL emitted from the light emission unit 432 is focused into the free layer 412 by the lens 434. Since the free layer 412 is irradiated with the pulsed light, the magnetic order of the topological ferrimagnet in the free layer 412 is reversed when an intensity of the irradiation light is equal to or greater than a threshold, and the magnetic order reversal does not occur when the intensity of the irradiation light is less than the threshold.

Unlike the writing methods by SOT and STT, the all-optical toggle switching allows the magnetic order reversal using light's heat, without the need for an electric current. By the all-optical toggle switching, the magnetic order of the topological ferrimagnet can be reversed in approximately 10 ps. When the magnetoresistance element of FIG. 3A or FIG. 3B is used, a magnetic order of the ferromagnetic layer closest to the ferrimagnetic layer is also reversed concurrently with the magnetic order reversal of the ferrimagnetic layer.

To read out data stored in the magnetoresistance element 410, the magnetoresistance effect can be utilized as shown in FIG. 6.

A plurality of magnetic memory elements 400 may be arranged to constitute a magnetic memory device.

Although MTJ elements are shown as examples of the magnetoresistance elements 210, 310, and 410 in FIGS. 5 to 7, these magnetoresistance elements can serve as giant magnetoresistance (GMR) elements as well. In this case, the non-magnetic layers 214, 314, and 414 are made of a metal (conductor).

### Second Embodiment

As described above, the topological ferrimagnet can exhibit the large anomalous Hall effect. Therefore, in the second embodiment, a magnetic memory element that uses the anomalous Hall effect to read data will be explained.

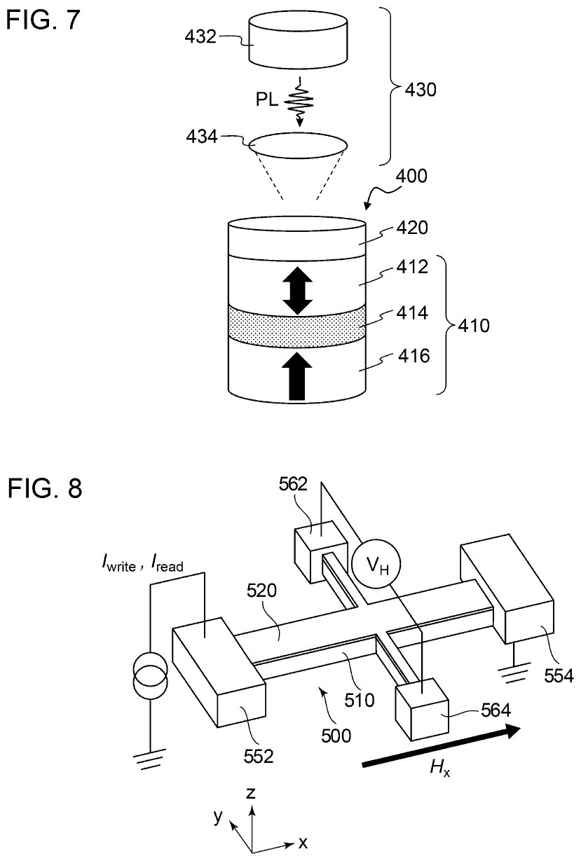

FIG. 8 shows a configuration of the magnetic memory element 500 with a Hall bar structure according to the second embodiment. The magnetic memory element 500 includes a ferrimagnetic layer 510 and a spin Hall layer 520 in contact with the ferrimagnetic layer 510. The ferrimagnetic layer 510 is made of the topological ferrimagnet as with the ferrimagnetic layer 1121, the first ferrimagnetic layer 1221, and the free layer 132 shown in FIGS. 3A to 3C. The spin Hall layer 520 is made of a material that exhibits a spin Hall effect (e.g., a non-magnetic heavy metal such as Ta, W, and Pt, or a chalcogenide material such as a topological insulator).

A pair of electrodes 552 and 554 made of Au/Ti is disposed on both ends of the magnetic memory element 500 in a longitudinal direction (x-direction), and a pair of electrodes 562 and 564 made of Au/Ti is disposed in a short direction (y-direction). A write current I_{write} or a read current I_{read} flows between the electrodes 552 and 554, and a Hall voltage V_{H} is detected between the electrodes 562 and 564.

To write information into the magnetic memory element 500, the write current I_{write} (pulsed current) flows through the spin Hall layer 520 in the longitudinal direction (x-direction). This write current generates a spin current in an out-of-plane direction (z-direction) by the spin Hall effect, and this spin current induces an SOT to act on the magnetic order (magnetization) of the ferrimagnetic layer 510, thereby allowing reversal of the magnetic order. Here, a weak bias field Hₓ applying in x-direction affects the magnetic order of the ferrimagnetic layer 510, and determines a rotational direction of the magnetic order.

In this way, the information (“0” or “1”) can be written into the ferrimagnetic layer 510. The direction of the magnetic order of the ferrimagnetic layer 510 can be manipulated depending on the direction of the write current write. For example, the write current I_{write} flowing in +x-direction reverses the magnetic order from +z-direction (“1”) to −z-direction (“0”), and the write current I_{write} flowing in-x-direction reverses the magnetic order from −z-direction (“0”) to +z-direction (“1”).

To read out the information stored in the ferrimagnetic layer 510, the read current I_{read} (direct current) flows through the ferrimagnetic layer 510 in x-direction. This read current generates the Hall voltage V_{H} in y-direction by the anomalous Hall effect. The sign of the Hall voltage V_{H} is determined depending on the z-component of the magnetic order of the ferrimagnetic layer 510. For example, +z-direction and −z-direction of the magnetic order of the ferrimagnetic layer 510 are equivalent to “1” and “0,” respectively. Thus, the information stored depending on the direction of the magnetic order of the ferrimagnetic layer 510 can be read out as the Hall voltage V_{H} by the read current I_{read}.

Unlike the magnetoresistance elements of the first embodiment, the magnetic memory element 500 of the second embodiment does not require a fixed layer and a non-magnetic layer in contact with the fixed layer, allowing for a simplified element structure and miniaturization.

The invention is not limited to the above-described embodiments, and various modifications can be made without departing from the scope of the invention.

### REFERENCE SIGNS LIST

100, 102, 104, 210, 310, 410: Magnetoresistance element
112, 122, 132, 212, 312, 412: Free layer
114, 124, 134, 214, 314, 414: Non-magnetic layer
116, 126, 136, 216, 316, 416: Fixed layer
118: Synthetic antiferromagnetic layer
200, 300, 400, 500: Magnetic memory element
220, 520: Spin Hall layer
510, 1121: Ferrimagnetic layer
1221: First ferrimagnetic layer
1123, 1223: First ferromagnetic layer
1161, 1261: Second ferromagnetic layer
1263: Second ferrimagnetic layer

1. A magnetic memory element comprising:
a magnetoresistance element including a free layer having a reversible magnetic order, a fixed layer having a fixed magnetic order, and a non-magnetic layer disposed between the free layer and the fixed layer, wherein
at least one of the free layer and the fixed layer is made of a topological ferrimagnet that exhibits an anomalous Hall effect and an anomalous Nernst effect.

2. The magnetic memory element according to claim 1, wherein
the free layer is made of the topological ferrimagnet at an angular momentum compensation point.

3. The magnetic memory element according to claim 2, further comprising a spin Hall layer in contact with the free layer and made of a material that exhibits a spin Hall effect, a write current flowing through the spin Hall layer in an in-plane direction being configured to generate a spin current in an out-of-plane direction, wherein
the spin current is configured to induce a spin-orbit torque that allows reversal of a magnetic order of the topological ferrimagnet in the free layer.

4. The magnetic memory element according to claim 2, wherein
a write current flowing through the magnetoresistance element in an out-of-plane direction is configured to induce a spin transfer torque that allows reversal of a magnetic order of the topological ferrimagnet in the free layer.

5. The magnetic memory element according to claim 2, wherein
the free layer is configured to be irradiated with ultrashort pulsed laser that allows reversal of a magnetic order of the topological ferrimagnet in the free layer.

6. The magnetic memory element according to claim 1, wherein
the free layer comprises:
a ferrimagnetic layer made of the topological ferrimagnet at an angular momentum compensation point; and
a ferromagnetic layer that is made of a ferromagnet, disposed between the non-magnetic layer and the ferrimagnetic layer, and has a thickness of 1 nm or less.

7. The magnetic memory element according to claim 1, wherein
the fixed layer is made of the topological ferrimagnet with a magnetic hardness parameter of 1 or higher.

8. The magnetic memory element according to claim 1, wherein
the free layer comprises:
a first ferrimagnetic layer made of the topological ferrimagnet at an angular momentum compensation point; and
a first ferromagnetic layer that is made of a ferromagnet, disposed between the non-magnetic layer and the first ferrimagnetic layer, and has a thickness of 1 nm or less, and
the fixed layer comprises:
a second ferrimagnetic layer made of the topological ferrimagnet with a magnetic hardness parameter of 1 or higher; and
a second ferromagnetic layer that is made of a ferromagnet, disposed between the non-magnetic layer and the second ferrimagnetic layer, and has a thickness of 1 nm or less.

9. The magnetic memory element according to claim 1, wherein
the free layer is made of the topological ferrimagnet at an angular momentum compensation point,
the fixed layer is made of the topological ferrimagnet with a magnetic hardness parameter of 1 or higher,
each of the topological ferrimagnet constituting the free layer and the topological ferrimagnet constituting the fixed layer is an alloy of a rare-earth element and a 3 d transition metal, and
in the free layer and the fixed layer, concentration of the rare-earth element increases with increasing distance from the non-magnetic layer in an out-of-plane direction, and concentration of the 3 d transition metal increases with decreasing distance from the non-magnetic layer in the out-of-plane direction.

10. The magnetic memory element according to claim 1, wherein
in the topological ferrimagnet, a magnetization compensation point and an angular momentum compensation point are different.

11. The magnetic memory element according to claim 10, wherein
the topological ferrimagnet is an alloy of a rare-earth element and a 3 d transition metal.

12. The magnetic memory element according to claim 11, wherein
a ratio of the rare-earth element to the 3 d transition metal in the topological ferrimagnet is in a range of 0.2 to 0.5.

13. A magnetic memory device comprising a plurality of magnetic memory elements, each of the plurality of magnetic memory elements being defined as the magnetic memory element according to claim 1.

14. A magnetic memory element comprising:
a ferrimagnetic layer made of a topological ferrimagnet that exhibits an anomalous Hall effect and an anomalous Nernst effect; and
a spin Hall layer in contact with the ferrimagnetic layer and made of a material that exhibits a spin Hall effect, a write current flowing through the spin Hall layer in an in-plane direction being configured to generate a spin current in an out-of-plane direction, wherein
the spin current is configured to induce a spin-orbit torque that allows reversal of a magnetic order of the topological ferrimagnet in the ferrimagnetic layer, and
a read current flowing through the ferrimagnetic layer in the in-plane direction is configured to generate an in-plane Hall voltage by the anomalous Hall effect in a direction perpendicular to the read current.

15. The magnetic memory element according to claim 14, wherein
the topological ferrimagnet is a ferrimagnet at an angular momentum compensation point.

16. The magnetic memory element according to claim 15, wherein
the topological ferrimagnet is an alloy of a rare-earth element and a 3 d transition metal.

17. The magnetic memory element according to claim 16, wherein
a ratio of the rare-earth element to the 3 d transition metal in the topological ferrimagnet is in a range of 0.2 to 0.5.

18. A magnetic memory device comprising a plurality of magnetic memory elements, each of the plurality of magnetic memory elements being defined as the magnetic memory element according to claim 14.
